(19) United States
(12) Patent Application Publication
(10) Pub. No.: US 2009/0294872 A1
(43) Pub. Date: Dec. 3, 2009

(54) Ge/Xe IMPLANTS TO REDUCE JUNCTION CAPACITANCE AND LEAKAGE

(75) Inventors: Xiangdong Chen, Poughquag, NY (US); Zhijiong Luo, Carmel, NY (US); Thomas Anthony Wallner, Pleasant Valley, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/128,938

(22) Filed: May 29, 2008

(51) Int. Cl. H01L 29/78; H01L 21/336

(52) U.S. Cl. 257/386; 438/290; 257/E21.409; 257/E29.255

(57) ABSTRACT

A method of reducing junction capacitance and leakage and a structure having reduced junction capacitance and leakage wherein germanium or xenon is implanted in the source and drain regions to at least partially deactivate the dopants in the source and drain regions.

### BACKGROUND OF THE INVENTION

It has been found that the ability to scale known MOSFET structures and processes is complicated by numerous concerns and competing factors. A shallow junction is needed for MOSFET scaling to control the short channel effect. But there is trade-off between abrupt junction and junction leakage, especially for the low power application. An abrupt junction is where the change of the doping from N to P or P to N is very steep. The abrupt junction will increase the junction leakage which is a big concern for low power applications.

Accordingly, it would be desirable to have MOSFET scaling without increasing junction capacitance and leakage.

Shih et al. U.S. Pat. No. 6,232,160, the disclosure of which is incorporated by reference herein, proposes suppressing the short-channel effect without increasing junction leakage and capacitance using a single delta-channel implant.

Brigham et al. U.S. Pat. Nos. 6,274,913 and 6,380,010, the disclosures of which are incorporated by reference herein, proposes a structure for reducing junction capacitance wherein the channel region is contiguous with the semiconductor substrate while the source and drain are substantially isolated from the silicon.

Divakaruni et al. U.S. Pat. No. 6,501,131, the disclosure of which is incorporated by reference herein, proposes a structure for suppressing short channel effect while providing low junction capacitance and leakage by providing a punch-through suppression implant (sometimes called anti-punch through doping) in the channel region.

The advantages of the invention will become more apparent after referring to the following description of the invention in conjunction with the accompanying drawings.

### BRIEF SUMMARY OF THE INVENTION

According to a first aspect of the invention, there is provided a method of reducing junction capacitance and leakage, the method comprising the steps of:

forming trench isolation regions in a semiconductor substrate;

forming a gate electrode structure between two trench isolation regions;

implanting source and drain regions adjacent to the gate electrode structure, the source and drain regions containing dopants; and

implanting germanium or xenon regions in the source and drain regions to at least partially deactivate the source and drain dopants.

According to a second aspect of the invention, there is provided a semiconductor structure having reduced junction capacitance and leakage comprising:

a semiconductor substrate having trench isolation regions;

a gate electrode structure formed between two trench isolation regions;

source and drain regions adjacent to the gate electrode structure, the source and drain regions containing dopants; and

implanted germanium or xenon regions in the source and drain regions to at least partially deactivate the source and drain dopants.

### BRIEF DESCRIPTION OF THE DRAWINGS

The features of the invention believed to be novel and the elements characteristic of the invention are set forth with particularity in the appended claims. The Figures are for illustration purposes only and are not drawn to scale. The invention itself, however, both as to organization and method of operation, may best be understood by reference to the detailed description which follows taken in conjunction with the accompanying drawings in which:

FIGS. 1A to 1G schematically illustrate the method of forming the structure having germanium or xenon implants according to the present invention.

FIG. 2 is a graph of normalized area junction capacitance illustrating a reduction of junction capacitance when germanium or xenon implants are utilized according to the present invention.

FIG. 3 is a graph of normalized side-wall junction capacitance illustrating a reduction of junction capacitance when germanium or xenon implants are utilized according to the present invention.

FIG. 4 is a graph of normalized GIDL leakage current illustrating a reduction of leakage current when germanium or xenon implants are utilized according to the present invention.

### DETAILED DESCRIPTION OF THE INVENTION

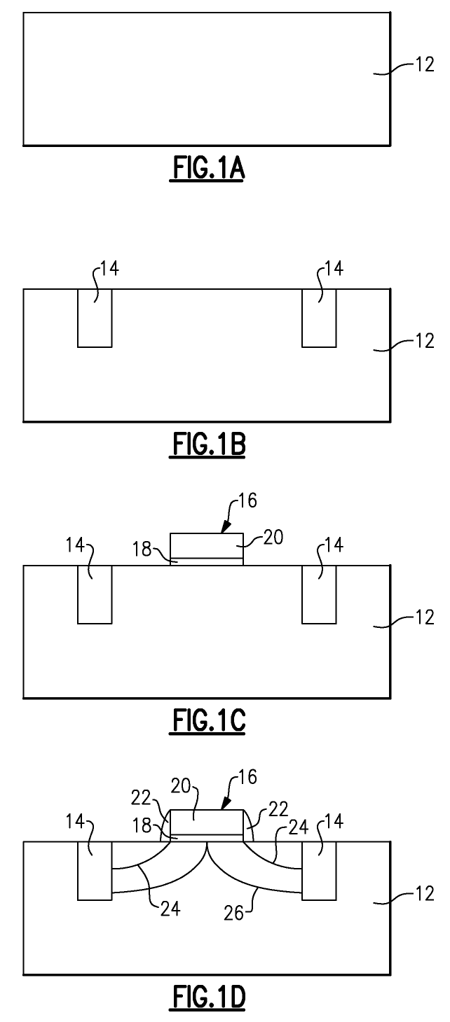

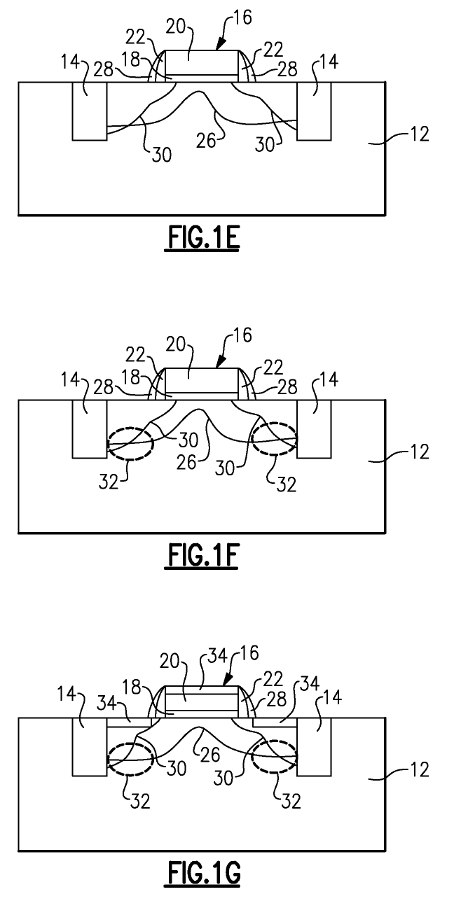

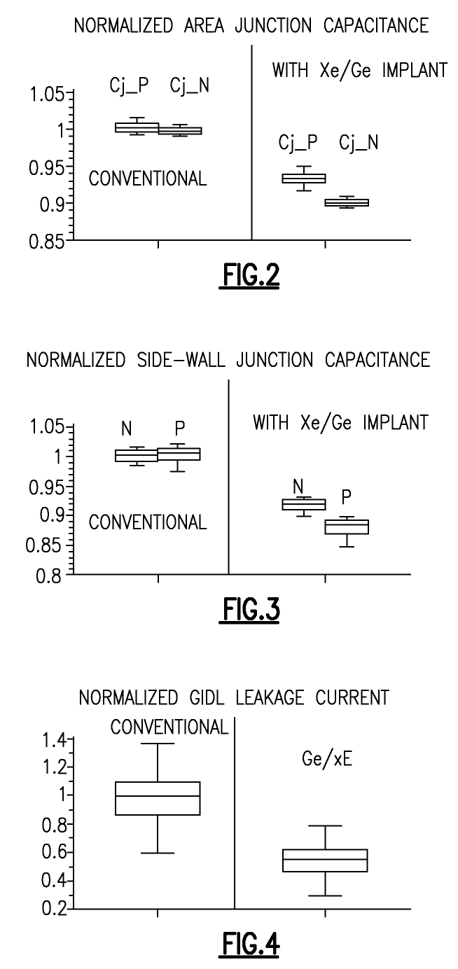

Referring now to the Figures in detail, FIGS. 1A through 1G schematically illustrate the process steps involved in forming the structure utilizing germanium (Ge) or xenon (Xe) implants according to the present invention. FIG. 1A schematically illustrates a silicon substrate 12 upon which the structure according to the present invention will be formed. The structure to be formed will be a MOSFET (metal oxide field effect transistor) device and, further, can be an NFET or PFET.

In FIG. 1B, conventional trench isolation regions 14 of oxide are formed.

The gate electrode 16 is conventionally formed on the silicon substrate 12 as schematically illustrated in FIG. 1C. As is typical, the gate electrode 16 may comprise layers of oxide or high-K material 18 and polysilicon or metal 20.

Referring now to FIG. 1D, sidewall spacers 22 of an insulator such as an oxide or nitride are formed on the sides of the gate electrode 16. Thereafter, source and drain extensions 24 are formed. It is understood by those skilled in the art that a mask is conventionally used for the formation of such source and drain extensions 24. If the device is an NFET device, the source and drain extensions can be low energy phosphorus (P) or arsenic (As) implants. Alternatively, if the device is a PFET device, the source and drain extensions 24 can be low energy boron (B) or boron fluoride (BF₂). Preferably, there is also a halo implant. Halo implant doping 26 is often used to provide a region of enhanced channel doping at the perimeter of the source and drain regions. For NFET devices, the supplemental halo implant doping 26 can be angled B or BF₂ with tilt angle from 10 to 40 degrees while for PFET devices, the supplemental halo implant doping 26 can be angled As or P with tilt angle from 10 to 40 degrees. A mask is used to block the PFET device for NFET halo/extension implants and similarly, a mask is used to block the NFET device for PFET halo/extension implants.

Thereafter, a second spacer 28 is formed as schematically illustrated in FIG. 1E. The second spacer 28 may be formed from a nitride or an oxide. Thereafter, a deep source and drain implant is performed to result in source and drain regions 30. As and P can be used for NFET devices and BF₂ or B can be used for PFET devices. The dose can be 1×10¹⁵ to 4×10¹⁵ atoms/cm². The depth of the source/drain junction is from 50 nm to 150 nm. Preferably, the deep source and drain implant is followed by an anneal to to activate the dopant and remove the damage caused by the implant. The silicon substrate 12 can be annealed at a temperature from 950 to 1100° C. for 5 seconds.

As shown now in FIG. 1F, the Ge or Xe implants according to the present invention are performed to at least partially or totally deactivate the doping in the source and drain regions. Ge or Xe are blanket implanted (i.e., no mask) at a dosage of about 1×10¹⁴ to 1×10¹⁵ atoms/cm² and an energy of about 10 to 40 KeV. The Ge or Xe implanted regions 32 are schematically illustrated in FIG. 1F. If desired, a mixture of Ge and Xe can be implanted but it is believed that it is not necessary and there is no benefit in doing so.

Finally, the partially completed MOSFET device is silicided to form silicided regions 34 as schematically illustrated in FIG. 1G.

The MOSFET devices prepared according to the present invention were found to have reduced junction capacitance and junction leakage without degrading the short channel control.

MOSFET devices were prepared by the process steps according to the present invention and compared to MOSFET devices prepared according to a conventional process without the Ge or Xe implant. Results of the comparisons are shown in FIGS. 2 to 4. FIG. 2 illustrates a comparison of normalized area junction capacitance for MOSFET devices prepared according to conventional practice and for MOSFET devices prepared according to the present invention wherein Cj_N is the area junction capacitance between source/drain to well of the NMOSFET and Cj_P is the area junction capacitance between the source/drain to well of the PMOSFET. FIG. 3 illustrates a comparison of normalized side-wall junction capacitance for MOSFET devices prepared according to conventional practice and for MOSFET devices prepared according to the present invention. FIG. 4 illustrates a comparison of normalized GIDL (Gate Induced Drain Leakage) for MOSFET devices prepared according to conventional practice and for MOSFET devices prepared according to the present invention. With respect to FIGS. 2 to 4, “normalized” means the capacitance or current is normalized to the mean value of the conventional device. The MOSFET devices prepared according to the present invention in all cases had Xe implants. Data for the inventive MOSFET devices, i.e., those having Xe implants in this case, are shown on the right side of the graphs while conventional MOSFET devices are shown on the left side of the graphs. It can seen that the inventive MOSFET devices have markedly and unexpectedly reduced area junction capacitance, side-wall junction capacitance and GIDL leakage current.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

1. A method of reducing junction capacitance and leakage, the method comprising the steps of:
forming trench isolation regions in a semiconductor substrate;
forming a gate electrode structure between two trench isolation regions, the gate electrode structure having sides;
forming at least one sidewall spacer on the sides of the gate electrode structure;
implanting source and drain regions adjacent to the gate electrode structure, the source and drain regions containing dopants; and
while the at least one sidewall spacer formed on the sides of the gate electrode structure is in place, implanting germanium or xenon regions in the source and drain regions to at least partially deactivate the source and drain dopants.

2. The method of claim 1 further comprising the step of annealing the source and drain implanted regions prior to the step of implanting germanium or xenon.

3. The method of claim 1 further comprising the step of siliciding the gate electrode structure after the step of implanting germanium or xenon.

4. The method of claim 1 further comprising the step of halo implanting doping between the steps of implanting source and drain regions and implanting germanium or xenon.

5. The method of claim 1 wherein implanting germanium or xenon is done by blanket implanting.

6. The method of claim 1 wherein the implanting of germanium or xenon is done at a dosage between about 1×10¹⁴ and 1×10¹⁵ atoms/cm² and at an energy between about 10 and 40 KeV.

7. A semiconductor structure having reduced junction capacitance and leakage comprising:
a semiconductor substrate having trench isolation regions;
a gate electrode structure formed between two trench isolation regions, the gate electrode structure having sides;
at least one sidewall spacer formed on the sides of the gate electrode structure;
source and drain regions adjacent to the gate electrode structure, the source and drain regions containing dopants; and
implanted germanium or xenon regions in the source and drain regions to at least partially deactivate the source and drain dopants.

8. The structure of claim 7 wherein the gate electrode structure is silicided.

9. The structure of claim 7 further comprising a halo implant doping in the source and drain regions.

10. The structure of claim 7 wherein the germanium or xenon is implanted at a dosage between about 1×10¹⁴ and 1×10¹⁵ atoms/cm² .

11. The structure of claim 7 wherein the semiconductor structure comprises a MOSFET having implanted germanium or xenon regions.

12. The method of claim 1 wherein the implanted germanium or xenon regions are adjacent to the trench isolation regions.

13. The method of claim 1 wherein a MOSFET is formed and further comprising the step of testing the MOSFET having the implanted germanium or xenon regions for junction capacitance and leakage.

14. The structure of claim 7 wherein the implanted germanium or xenon regions are adjacent to the trench isolation regions.
